(19) United States
(12) Patent Application Publication
(10) Pub. No.: US 2026/0082713 A1
(43) Pub. Date: Mar. 19, 2026

(54) IMAGE SENSOR PACKAGE

(71) Applicant: SAMSUNG ELECTRONICS CO., LTD., Suwon-si (KR)

(72) Inventors: Sunwoo HAN, Suwon-si (KR); Wansun KIM, Suwon-si (KR); Shlege LEE, Suwon-si (KR)

(73) Assignee: SAMSUNG ELECTRONICS CO., LTD., Suwon-si (KR)

(21) Appl. No.: 19/049,474

(22) Filed: Feb. 10, 2025

(30) Foreign Application Priority Data
Sep. 13, 2024 (KR) 10-2024-0125705

(51) Int. Cl. H10F 39/00

(52) U.S. Cl. CPC H10F 39/804; H10F 39/811; H10F 39/8057

(57) ABSTRACT

An image sensor package includes a package substrate, an image sensor chip disposed on the package substrate and including a pixel array region and a pad, a dam disposed in the pad region of the image sensor chip and disposed on at least a portion of the plurality of chip pads, a transparent cover disposed on the dam and having a first portion, and a second portion, located outside of the first portion, and an encapsulant. The dam has a lower surface contacting the pad region and an upper surface facing opposite the lower surface. The first portion contacts a portion of the upper surface of the dam. A width of a contact region between the first portion and the portion of the upper surface of the dam in a first direction is smaller than a width of the upper surface of the dam in the first direction.

### CROSS-REFERENCE TO RELATED APPLICATION(S)

This application is based on and claims priority to Korean Patent Application No. 10-2024-0125705, filed on Sep. 13, 2024, in the Korean Intellectual Property Office, the entire disclosure of which is herein incorporated by reference in its entirety.

### BACKGROUND

One or more example embodiments of the disclosure relate to an image sensor package.

An image sensor is a semiconductor-based sensor receiving light and generating an electrical signal, and may include a pixel array having a plurality of pixels, a logic circuit for driving the pixel array and generating an image, and the like. Each of the pixels may include a photodiode and a pixel circuit for converting charges generated by the photodiode into an electrical signal.

### SUMMARY

One or more example embodiments provide an image sensor package that may have improved reliability.

According to an aspect of one or more example embodiments, an image sensor package includes a package substrate; an image sensor chip disposed on the package substrate and including a pixel array region, in which active pixels are arranged, and a pad region located outside the pixel array region, a plurality of chip pads being disposed in the pad region; a dam disposed in the pad region of the image sensor chip, the dam being provided on at least a portion of the plurality of chip pads; a transparent cover disposed on the dam, the transparent cover having a first portion, and a second portion located outside of the first portion; and an encapsulant provided on at least a portion of a side surface of the image sensor chip and at least a portion of a side surface of the dam. The dam has a lower surface contacting the pad region and an upper surface facing opposite to the lower surface. The first portion contacts a portion of the upper surface of the dam. A width of a contact region between the first portion and the portion of the upper surface of the dam in a first direction is smaller than a width of the upper surface of the dam in the first direction.

According to an aspect of one or more example embodiments, an image sensor package includes a package substrate; an image sensor chip disposed on the package substrate and including active pixels arranged in a central portion of the image sensor chip; a dam surrounding the active pixels and disposed along an outer region of the image sensor chip; a transparent cover provided on the dam; and an encapsulant provided on at least a portion of a side surface of the image sensor chip and at least a portion of a side surface of the dam. The dam overlaps the transparent cover in a vertical direction, and at least a portion of the transparent cover is spaced apart from an upper surface of the dam in the vertical direction.

According to an aspect of one or more example embodiments, an image sensor package includes a package substrate including a plurality of upper pads; an image sensor chip disposed on the package substrate, the image sensor chip including a pixel array region, in which active pixels are arranged, and a pad region located outside of the pixel array region, a plurality of chip pads being disposed in the pad region; a conductive wire electrically connecting the plurality of upper pads of the package substrate and the plurality of chip pads of the image sensor chip; a dam disposed on the pad region of the image sensor chip, the dam being provided on at least respective portions of the plurality of chip pads and the conductive wire; a transparent cover provided on the dam; and an encapsulant provided on at least a portion of a side surface of the image sensor chip and at least a portion of a side surface of the dam. A portion of an upper surface of the dam is in contact with a lower surface of the transparent cover, and another portion of the upper surface of the dam is in contact with the encapsulant.

### BRIEF DESCRIPTION OF DRAWINGS

The above and other aspects, features, and advantages of the disclosure will be more clearly understood from the following detailed description, taken in conjunction with the accompanying drawings, in which:

FIG. 1 is a cross-sectional view illustrating an image sensor package according to one or more example embodiments;

FIG. 2 is a plan view illustrating a cross-section taken along a line X-X′ of FIG. 1;

FIG. 3A is a partially enlarged view illustrating an area corresponding to area ‘A’ of FIG. 1 in an image sensor package according to one or more example embodiments, and FIG. 3B is a partially enlarged view illustrating an area corresponding to area ‘B’ of FIG. 1 in an image sensor package according to one or more example embodiments;

FIG. 4 is a cross-sectional view illustrating an image sensor package according to one or more example embodiments;

FIG. 5 is a cross-sectional view illustrating an image sensor package according to one or more example embodiments;

FIG. 6 is a cross-sectional view illustrating an image sensor package according to one or more example embodiments;

FIG. 7 is a plan view illustrating a cross-section taken along a line Y-Y′ of FIG. 6;

FIG. 8 is a cross-sectional view illustrating an image sensor package according to one or more example embodiments;

FIG. 9 is a plan view illustrating a cross-section taken along a line Z-Z′ of FIG. 8; and

FIGS. 10A to 10F are cross-sectional views schematically illustrating a process of manufacturing an image sensor package according to one or more example embodiments.

### DETAILED DESCRIPTION

Hereinafter, example embodiments will be described with reference to the attached drawings. Unless otherwise specifically stated, in this specification, terms such as ‘on,’ ‘upper surface,’ ‘below,’ ‘lower surface,’ ‘side surface,’ and the like are based on the drawings, and may actually vary depending on the direction in which components are disposed.

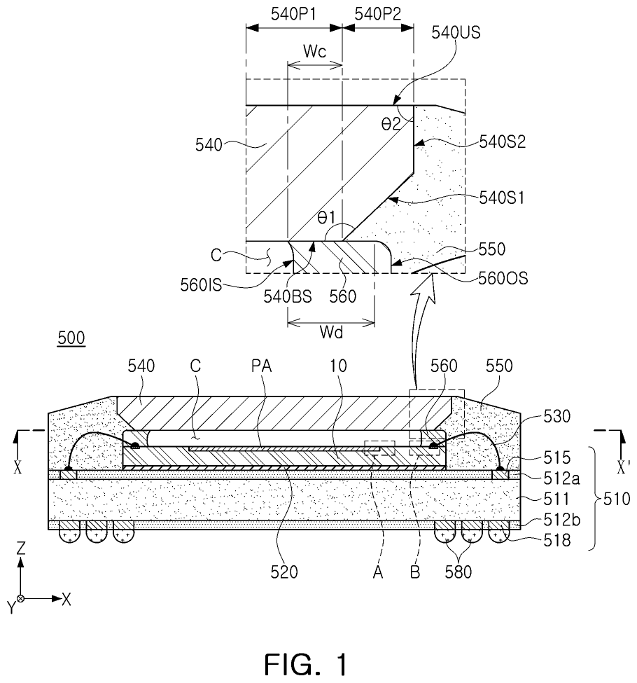

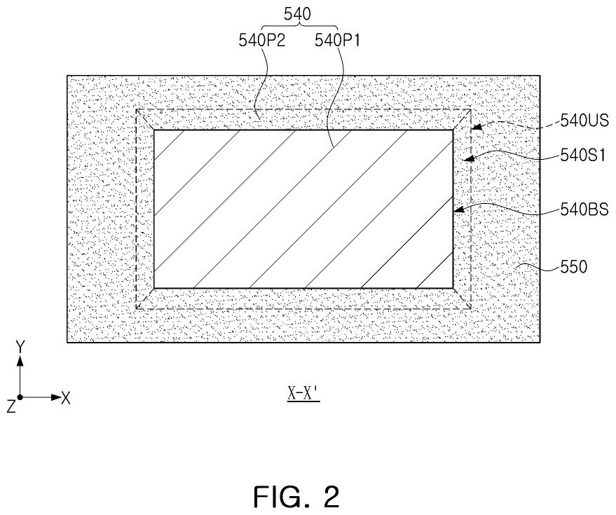

FIG. 1 is a cross-sectional view illustrating an image sensor package according to one or more example embodiments, and FIG. 2 is a plan view illustrating a cross-section taken along a line X-X′ of FIG. 1.

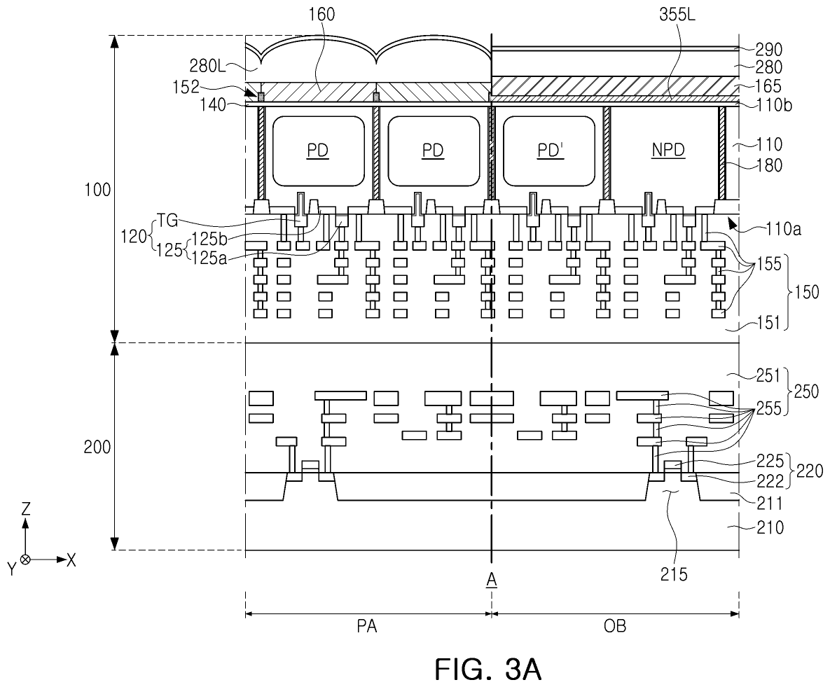

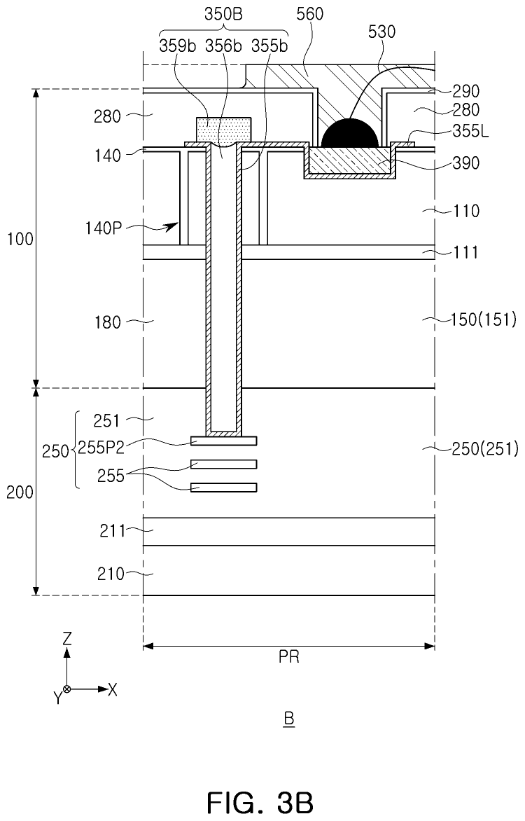

FIG. 3A is a partially enlarged view illustrating an area corresponding to area ‘A’ of FIG. 1 in an image sensor package according to one or more example embodiments, and FIG. 3B is a partially enlarged view illustrating an area corresponding to area ‘B’ of FIG. 1 in an image sensor package 500 according to one or more example embodiments. FIG. 3A is a partially enlarged view illustrating a pixel array region (PA) and a light-shielding area (OB) of an image sensor chip 10, and FIG. 3B corresponds to a partially enlarged view illustrating a pad region (PR) of an image sensor chip 10.

Referring to FIGS. 1 to 3B, an image sensor package 500 of one or more example embodiments may include a package substrate 510, an image sensor chip 10, a dam 560, a transparent cover 540, and an encapsulant 550. Referring to FIGS. 1 to 3B, the image sensor package 500 of one or more example embodiments may further include a conductive wire 530 and external connection conductors 580.

The package substrate 510 may include a substrate body 511, an upper pad 515, a lower pad 518, and upper and lower passivation layers 512a and 512b. For example, the substrate body 511 may include silicon, ceramic, organic matter, glass, epoxy resin, or the like. In some embodiments, the package substrate 510 may be a printed circuit board (PCB). The substrate body 511 may include single-layer or multi-layer interconnections. The interconnections of the substrate body 511 may electrically connect the upper pad 515 and the lower pad 518.

The image sensor chip 10 may be disposed on the package substrate 510 and may be mounted on the package substrate 510, in a wire bonding structure. The image sensor chip 10 may be mounted in a manner such that the pixel array region (PA) of the image sensor chip 10 faces upward, and may be bonded to the package substrate 510 by an adhesive layer 520. A plurality of chip pads 390 disposed within a pad region (PR) of the image sensor chip 10 may be electrically connected to a corresponding plurality of upper pads 515 of the package substrate 510 by conductive wires 530. A detailed description of the image sensor chip 10 will be described later.

The dam 560 may have a quadrangular ring shape surrounding a peripheral area of an upper surface of the image sensor chip 10. The dam 560 may be disposed in a peripheral area of the upper surface of the image sensor chip 10, for example, in the pad region (PR) of the image sensor chip 10. The dam 560 may be spaced apart from the pixel array region (PA) and surround the pixel array region (PA), but is not limited thereto. The dam 560 may be formed to cover the plurality of chip pads 390 and the conductive wire 530 of the image sensor chip 10. The dam 560 may have a lower surface contacting the plurality of chip pads 390 of the image sensor chip 10 and an upper surface positioned opposite to the lower surface. The lower surface of the dam 560 may contact an upper surface of a second protective layer 290 that conformally extends along the upper surface of the image sensor chip 10. A portion of the upper surface of the dam 560 may be in contact with a lower surface (or lowermost surface) 540BS of the transparent cover 540, and another portion of the upper surface of the dam may be in contact with the encapsulant 550, but is not limited thereto. The dam 560 may have an inner side surface 560IS and an outer side surface 560OS connected to the upper surface and the lower surface, respectively. The inner side surface 560IS of the dam 560 may have a concave curved shape toward the dam 560, but is not limited thereto. A lower end of the inner side surface 560IS of the dam 560 may be in contact with an upper surface of the second protective layer 290 of the image sensor chip 10, and an upper end of the inner side surface 560IS of the dam 560 may be in contact with the lower surface 540BS of the transparent cover 540. One end of the outer side surface 560OS of the dam 560 may be in contact with the lower surface 540BS of the transparent cover 540, a lower end of the outer side surface 560OS of the dam 560 may be in contact with the upper surface of the second protective layer 290 of the image sensor chip 10, and an upper end of the outer side surface 560OS of the dam 560 may be spaced apart from a second portion 540P2 of the transparent cover 540 in a vertical direction (e.g., Z-axis direction) and may be in contact with the encapsulant 550. At least a portion of the upper end of the outer side surface 560OS of the dam 560 may have a rounded shape and a convex curved shape toward the encapsulant 550, but is not limited thereto.

In the image sensor package 500, thermal stress may be applied to the dam 560 due to a difference in thermal expansion coefficient between the image sensor chip 10 and the dam 560, and between the transparent cover 540 and the dam 560. This thermal stress may be transmitted to the second protective layer 290 that is disposed on top of the image sensor chip 10 and is in contact with the dam 560, and a crack may occur in the second protective layer 290, causing an appearance defect, and further, peeling may occur due to this crack. Thus, a reliability of the image sensor chip 10 may be degraded due to moisture or a foreign substance introduced from an outside.

To prevent a defect due to such thermal stress, a structure may be introduced in which only a first portion 540P1 corresponding to a portion of the transparent cover 540 comes into contact with the dam 560. A width of a contact surface in a first direction (for example, X-axis direction) between a portion of the upper surface of the dam 560 and the transparent cover 540 may be smaller than a width of the upper surface of the dam 560 in the first direction. Therefore, a contact area between the transparent cover 540 and the dam 560 may be reduced, thereby significantly reducing an influence of thermal stress and effectively preventing damage such as cracks.

The transparent cover 540 may be disposed on the image sensor chip 10. The dam 560 may be disposed on a peripheral area of the image sensor chip 10, and the transparent cover 540 may be disposed on the dam 560, and at least a portion of the transparent cover 540 may vertically overlap with the dam 560. The dam 560 may support the transparent cover 540 on the image sensor chip 10. The transparent cover 540 may be disposed to be spaced apart from the upper surface of the image sensor chip 10 by a height of the dam 560. At least a portion of the transparent cover 540 may be disposed so as not to vertically overlap with the dam 560, but is not limited thereto. A space (C) may exist between the transparent cover 540 and the image sensor chip 10. The space (C) may be surrounded by the dam 560. For example, the transparent cover 540 may include, but is not limited to, transparent glass, transparent resin, or light-transmitting ceramic.

The transparent cover 540 may have the first portion 540P1 and the second portion 540P2 positioned outside the first portion 540P1. The first portion 540P1 may be in contact with at least a portion of the upper surface of the dam 560, and the second portion 540P2 may be spaced apart from the upper surface of the dam 560 in a vertical direction. A width (Wc) of the contact surface between the first portion 540P1 of the transparent cover 540 and the portion of the upper surface of the dam 560 in the first direction may be smaller than a width (Wd) of the upper surface of the dam 560 in the first direction. A ratio (Wc/Wd) of the width (Wc) of the contact surface in the first direction to the width (Wd) of the upper surface of the dam 560 in the first direction may be about ⅕ or greater, for example, in a range of about ⅕ to about ½, but is not limited thereto. For example, if the ratio is less than about ⅕, the contact region between the lowermost surface 540BS of the transparent cover 540 and the upper surface of the dam 560 may not be sufficient, and thus, it may be difficult to support and fix the transparent cover 540. For example, if the ratio exceeds about ½, the contact region between the lowermost surface 540BS of the transparent cover 540 and the upper surface of the dam 560 is relatively wide, such that in the image sensor package of the present embodiment, a degree to which thermal stress applied to the dam 560 is alleviated may be insufficient due to mitigation of a difference in thermal expansion coefficient between the transparent cover 540 and the dam 560. In a planar view, the second portion 540P2 may be disposed along a perimeter of the first portion 540P1. In one or more example embodiments, the first portion 540P1 may correspond to a region including a central portion of the transparent cover 540, may vertically overlap with the image sensor chip 10, and may vertically overlap with at least a portion of the dam 560. At least a portion of the second portion 540P2 may vertically overlap with the dam 560, but is not limited thereto. The second portion 540P2 may not overlap with the dam 560 in the vertical direction, and may include an overhang portion that protrudes in the first direction (for example, in the X-axis direction) more than the dam 560 in a planar view. The second portion 540P2 of the transparent cover 540 may have an inclined surface 540S1 extending from one end of the lowermost surface 540BS, and the inclined surface 540S1 may extend along a perimeter of the transparent cover 540. A first dihedral angle θ1 between the lowermost surface 540BS of the transparent cover 540 and the inclined surface 540S1 may be an obtuse angle, but is not limited thereto. The inclined surface 540S1 may be spaced apart from the upper surface of the dam 560 in the vertical direction, and the inclined surface 540S1 may come into contact with the encapsulant 550. The second portion 540P2 of the transparent cover 540 has a side surface 540S2 extending from one end of an uppermost surface 540US of the transparent cover 540, and the side surface 540S2 may be positioned along the perimeter of the transparent cover 540. The transparent cover 540 may have a shape in which the side surface 540S2 positioned in the upper region extends from the uppermost surface 540US in a direction perpendicular to the uppermost surface 540US, and a second dihedral angle θ2 between the uppermost surface 540US and the side surface 540S2 may be smaller than the first dihedral angle θ1, but is not limited thereto. The side surface 540S2 and the inclined surface 540S1 of the transparent cover 540 may be directly connected. A width of the lowermost surface 540BS of the transparent cover 540 in the first direction (for example, X-axis direction) may be a first width, and the width of the uppermost surface 540US of the transparent cover 540 in the first direction may be a second width that is larger than the first width.

The encapsulant 550 may be disposed on the package substrate 510 and may seal the image sensor chip 10, the wire conductive 530, and the transparent cover 540. In detail, the encapsulant 550 may be formed to cover the image sensor chip 10 and a side surface of the transparent cover 540 from the upper surface of the package substrate 510. In addition, the encapsulant 510 may cover the conductive wire 530 and an outer side surface of the dam 560. In the present embodiment, the encapsulant 550 may have a side surface that is substantially coplanar with a side surface of the package substrate 510. For example, the encapsulant 550 may include an Epoxy Molding Compound (EMC).

The external connection conductors 580 may be disposed on a lower surface of the package substrate 510. The external connection conductors 580 may be electrically connected to the image sensor chip 10 through the lower pads 518. The image sensor package 500 may be electrically connected to an external device, such as a module substrate, a system board, and the like through the external connection conductors 580. For example, the external connection conductors 580 may include a low melting point metal, such as tin (Sn) or a tin-silver-copper (Sn—Ag—Cu) alloy or a tin-aluminum-copper (Sn—Al—Cu) alloy containing tin (Sn). According to one or more example embodiments, the lower passivation layer 512b may include a resist layer that protects the external connection conductors 580 from external physical and chemical damage.

Referring to FIG. 3A, the image sensor chip 10 may include a first chip 100 and a second chip 200 that are stacked and electrically connected to each other.

The first chip 100 may include the pixel array region (PA) in which a plurality of pixels are disposed in a two-dimensional array structure, and the second chip 200 may include a logic area in which logic elements are disposed. The logic elements included in the logic area may be electrically connected to the plurality of pixels of the pixel array region, and may provide signals to the pixels or process signals output from the pixels. For example, the logic area may include at least one of a control register block, a timing generator, a ramp signal generator, a row driver, a readout circuit, and a buffer.

The first chip 100 may include a light-shielding area (OB) and a pad region (PR) disposed in order from the pixel array region (PA). The pixel array region (PA) and the light-shielding area (OB) may also be referred to as a sensor array region (SAR).

In the pixel array region (PA), active pixels configured to receive light and generate an active signal may be arranged. In the light-shielding area (OB), optical black pixels configured to block light and generate an optical black signal may be arranged. The light-shielding area (OB) may be disposed along a periphery of the pixel array region (PA), for example, but this is only an example. In some embodiments, dummy pixels may be disposed in the pixel array region (PA) adjacent to the light-shielding area (OB).

The pad region (PR) may be disposed adjacent to the light-shielding area (OB). In some embodiments, the pad region (PR) may be disposed adjacent to an edge of the image sensor chip 10. In this embodiment, the pad region (PR) is illustrated as being disposed along four edges of the image sensor chip 10, but may be disposed at opposite edges or may be disposed to surround almost an entirety of the first chip 100. The pad region (PR) may include a plurality of pads used for electrically connecting to an external device, and may be configured to transmit and receive electrical signals between the image sensor chip 10 and the external device.

The arrangement of the pixel array region (PA), the light-shielding area (OB), and the pad region (PR) may be varied as needed.

Referring to FIGS. 3A and 3B, the first chip 100 of an image sensor chip 10 according to the present embodiments may include a first substrate 110 having a lower surface 110a and an upper surface 110b, a device isolation film 111 defining an active area on a lower surface 110a of the first substrate 110, first circuit elements 120 on the active area of the lower surface 110a of the first substrate 110, and a first interconnection structure 150 between a lower surface of the first substrate 110 and a second chip 200. The upper surface 110b of the first substrate 110 may be referred to as a first side or back side, and the lower surface 110a of the first substrate 110 may be referred to as a second side or front side. The upper surface 110b of the first substrate 110 may be a light-receiving surface on which light is incident. The image sensor according to the present embodiment may be a back-illuminated (BSI) image sensor.

As illustrated in FIG. 3A, in the pixel array region (PA), the first chip 100 may include a surface insulating layer 140 on the upper surface 110b of the first substrate 110, a grid pattern 152 on the surface insulating layer 140, color filters 160 covering the surface insulating layer 140 and the grid pattern 152, and microlens layer 280L on the color filters 160. In addition, in the light-shielding area (OB), the first chip 100 may further include a conductive layer 355L on the horizontal insulating layer 140, a light-shielding filter layer 165 on the conductive layer 355L, and a first protective layer 280 and the second protective layer 290 covering the light-shielding filter layer 165.

The second chip 200 may be disposed on a lower surface of the first chip 100. Referring to FIG. 3A, the second chip 200 may include a second substrate 210, a device isolation film 211 defining an active area 215 on the second substrate 210, second circuit elements 220 on the second substrate 210, and a second interconnection structure 250 electrically connected to the second circuit elements 220. The second circuit elements 220 may include elements such as transistors including a gate 225 and a source/drain 222.

The first substrate 110 may be a semiconductor substrate. For example, the first substrate 110 may be bulk silicon or a silicon-on-insulator (SOI). The first substrate 110 may be a silicon substrate, or may include other materials, such as silicon-germanium (SiGe), indium antimonide, lead telluride, indium arsenide, indium phosphide, gallium arsenide, or gallium antimonide. Alternatively, the first substrate 110 may have a structure in which an epitaxial layer is formed on a base substrate. A plurality of unit pixels may be disposed in the first substrate 110 in the sensor array region (SAR). For example, a plurality of pixels may be formed within a pixel array region (PA) in a two-dimensional (for example, matrix) arrangement on a plane including a first direction (e.g., X direction) and a second direction (e.g., Y direction).

Each unit pixel may include a photoelectric conversion element (PD). The photoelectric conversion element (PD) may be disposed within a first substrate 110 of the pixel array region (PA). The photoelectric conversion element (PD) may generate charges in proportion to the amount of light incident from the outside. For example, the photoelectric conversion element (PD) may include at least one of a photo diode, a photo transistor, a photo gate, a pinned photo diode, an organic photo diode, a quantum dot, and any combination thereof, but are not limited thereto.

The first circuit elements 120 may include a transfer gate (TG) and active elements 125. The active elements 125 may each include a gate 125a and a source/drain 125b. The transfer gate (TG) may transfer charge from an adjacent photoelectric conversion element (PD) to an adjacent floating diffusion region, and the active elements 125 may include a transistor connected to the photoelectric conversion elements (PD) to process an electrical signal, and may be at least one of a source follower transistor, a reset transistor, and a selection transistor. The transfer gate (TG) may be a vertical transistor gate that includes a portion extending from the lower surface 110b of the first substrate 110 into the first substrate 110.

A pixel separation pattern 180 may be disposed within the first substrate 110 of the sensor array region (SAR). The pixel separation pattern 180 may define a plurality of unit pixels. The pixel separation pattern 180 may be disposed to surround respective photoelectric conversion elements (PD). The pixel separation pattern 180 may be disposed in a grid shape in a planar view to separate a plurality of pixels from each other.

In the present embodiment, the pixel separation pattern 180 may penetrate at least a portion of the first substrate 110. In some embodiments, the pixel separation pattern 180 may include a trench extending from the lower surface 110a to the upper surface 110b, and may have a structure in which an insulating material is buried in the trench. The pixel separation pattern 180 may include a separation insulating layer formed on a sidewall of the trench, and a filling portion surrounded by the separation insulating layer. For example, the separation insulating layer may include silicon oxide, and the filling portion may include polysilicon.

In this embodiment, the pixel separation pattern 180 may be in contact with the element separation film 111. The element separation film 111 may be disposed on the lower surface 110a of the first substrate 110 as described above and may define an active area. For example, the element separation film 111 may include an insulating material such as silicon oxide.

Referring to FIG. 3A, in the light-shielding area (OB), a first reference area (or dummy photoelectric conversion elements) (PD′) formed in the same manner as the photoelectric conversion elements (PD) and a second reference area (NPD) in which the photoelectric conversion elements (PD) are not formed may be provided. The second reference area (NPD) may be a comparison area that does not include the photoelectric conversion elements (PD) or a comparison area that does not include the photodiode of the photoelectric conversion elements (PD). For example, the dummy photoelectric conversion elements (PD′) may be disposed within the first substrate 110 of the light-shielding area (OB) adjacent to the pixel array region (PA), but may not be disposed within the first substrate 110 of the light-shielding area (OB) spaced apart from the pixel array region (PA). In the light-shielding area (OB), the first and second reference areas (PD,′ NPD) may be disposed within the first substrate 110 and may be separated by the pixel separation pattern 180.

The first interconnection structure 150 may be disposed on the lower surface of the first substrate 110. The first substrate 110 and the first interconnection structure 150 may constitute the first chip 100, where the first chip 100 may also be referred to as a ‘sensor chip’.

The first interconnection structure 150 may include a first inter-wiring insulating layer 151 and a plurality of first interconnections 155 on the first inter-wire insulating layer 151. The number of layers and arrangements of the interconnections constituting the first interconnection structure 150 illustrated in the drawing are merely illustrative and not limiting. The plurality of first interconnections 155 may include interconnection patterns on different levels and vias electrically connecting the interconnection patterns and the first circuit elements 120. The first inter-wiring insulating layer 151 may include at least one of, for example but not limited to, silicon oxide, silicon nitride, silicon oxynitride, and a low-κ material having a lower permittivity than silicon oxide. The first interconnections 155 may include at least one of, for example but not limited to, tungsten (W), copper (Cu), aluminum (Al), gold (Au), silver (Ag), and alloys thereof.

The second substrate 210 may be bulk silicon or silicon-on-insulator (SOI), similar to the first substrate 110. The second substrate 210 may be a silicon substrate, or may include other materials such as, for example but not limited to, silicon germanium, indium antimonide, lead telluride, indium arsenide, indium phosphide, gallium arsenide, or gallium antimonide. Alternatively, the second substrate 210 may be an epi layer formed on a base substrate. The second circuit elements 220 may be disposed on the second substrate 210. For example, the second circuit elements 220 may include transistors that constitute a control register block, a timing generator, a ramp signal generator, a row driver, a readout circuit, or a buffer.

The second interconnection structure 250 may be disposed on the second substrate 210. For example, the second interconnection structure 250 may be disposed between the first interconnection structure 150 of the first chip 100 and the second substrate 210. The second substrate 210 and the second interconnection structure 250 may constitute the second chip 200. In this case, the second chip 200 may also be referred to as a “logic chip.”

The second interconnection structure 250 may include a second inter-wiring insulating layer 251 and a plurality of second interconnections 255 on the second inter-wiring insulating layer 251. The number of layers and arrangement of the interconnections constituting the second interconnection structure 250 illustrated in the drawing are merely illustrative and not limiting. The plurality of first interconnections 255 may include interconnection patterns on different levels and vias electrically connecting the interconnection patterns and the second circuit elements 220. The second interconnection structure 250 may provide a path for transmitting and receiving electrical signals between the second circuit elements 220 and respective unit pixels of the sensor array region (SAR). The second inter-wiring insulating layer 251 may include at least one of, for example but not limited to, silicon oxide, silicon nitride, silicon oxynitride, and a low-κ material having a lower permittivity than silicon oxide. The second interconnections 255 may include at least one of, for example but not limited to, tungsten (W), copper (Cu), aluminum (Al), gold (Au), silver (Ag), and alloys thereof. In the present embodiment, the first interconnection structure 150 may be bonded to the second interconnection structure 250. In some embodiments, a bonding insulating film may be included at an interface between the first and second interconnection structures 150 and 250. The bonding insulating film may include at least one of silicon oxide, silicon nitride, silicon oxynitride, and silicon carbonitride (SiCN), but is not limited thereto.

The surface insulating layer 140 may be disposed on substantially the entire upper surface 110b of the first substrate 110. The surface insulating layer 140 may extend along the upper surface 110b of the first substrate 110 in the sensor array region (SAR), as well as in the peripheral area, for example, a chip-to-chip connection region (CR) and the pad region (PR). The surface insulating layer 140 may include an insulating material. For example, the surface insulating layer 140 may include at least one of silicon oxide, silicon nitride, silicon oxynitride, aluminum oxide, hafnium oxide, and any combination thereof.

In some embodiments, the surface insulating layer 140 may be a multilayer. The surface insulating layer 140 may function as an antireflection film, thereby preventing reflection of light incident on the first substrate 110 and improving a light reception rate of the photoelectric conversion elements (PD). In addition, the surface insulating layer 140 may function as a planarization film, thereby forming the color filter 170 and microlens layer 280L described below with a uniform height. For example, the surface insulating layer 140 may include an aluminum oxide film, a hafnium oxide film, a silicon oxide film, a silicon nitride film, and a hafnium oxide film, which are sequentially laminated on the upper surface 110b of the first substrate 110, but is not limited thereto.

The color filter 160 may be disposed on the surface insulating layer 140. The color filter 160 may be arranged to correspond to respective unit pixels of the pixel array region (PA). The color filter 160 may have various color filters depending on the unit pixel. For example, the color filter 160 may include a red color filter 160R, a green color filter 160G, and a blue color filter 160G. In some embodiments, the color filter 160 may be arranged in a Bayer pattern. However, this is only an example, and the color filter 170 may include a yellow filter, a magenta filter, and a cyan filter, and may further include a white filter.

In this embodiment, the grid pattern 152 may be disposed between the color filters 160. The grid pattern 152 may be disposed on the surface insulating layer 140. The grid pattern 152 may be interposed between the color filters 160. In some embodiments, the grid pattern 152 may be disposed to overlap with the pixel separation pattern 180 in a third direction (e.g., Z direction) that is vertical. In some embodiments, the grid pattern 152 may include a conductive pattern and a low refractive index pattern. The conductive pattern may effectively prevent electrostatic discharge (ESD) failure by preventing charges generated by ESD or the like from accumulating on the surface of the first substrate 110. The low refractive index pattern may improve a light collection efficiency by refracting or reflecting light incident obliquely, thereby improving a quality of the image sensor. For example, the conductive pattern may include, for example but is not limited to, at least one of titanium (Ti), titanium nitride (TiN), tantalum (Ta), tantalum nitride (TaN), tungsten (W), aluminum (Al), and copper (Cu), and the low refractive index pattern may include a low refractive index material having a refractive index lower than silicon (Si). For example, the low refractive index pattern may include, for example but is not limited to, at least one of silicon oxide, aluminum oxide, tantalum oxide, and any combination thereof.

The microlens layer 280L may be disposed on the color filter 160. The microlens layer 280L may be disposed on the active pixels, on the pixel array region (PA), and may include microlenses arranged to correspond to respective unit pixels of the pixel array region (PA). Each of the microlenses may have a convex shape and may have a predetermined radius of curvature. Accordingly, the microlenses may focus light incident on the photoelectric conversion elements (PD). The microlens layer 280L may include, for example, a light-transmitting resin. In some embodiments, the microlens layer 280L may extend to a portion of the peripheral area (for example, the light-shielding area (OB)).

Referring to FIG. 3A, the first chip 100 may further include the light-shielding filter layer 165. The light-shielding filter layer 165 may be disposed on the conductive layer 355L in the light-shielding area (OB). In some embodiments, the light-shielding filter layer 165 may extend from the light-shielding area (OB) to at least a portion of the pad region (PR) on the conductive layer 355L, but is not limited thereto. The light-shielding filter layer 165 may form a light-shielding pattern that blocks light together with the conductive layer 355L. The light-shielding filter layer 165 may be formed together with the color filters 160 and may have substantially the same thickness as the color filters 160, but is not limited thereto. The light-shielding filter layer 165 may include a blue color filter or a black filter.

In some embodiments, the light-shielding area (OB) may be used to remove a noise signal due to dark current. For example, in a state in which light is blocked by the conductive layer 355L and the light-shielding filter layer 165, the first reference area (PD′) including the photodiode may be used as a reference pixel for noise removal by the photodiode. In addition, in a state in which light is blocked by the conductive layer 355L and the light-shielding filter layer 165, the second reference area (NPD) not including the photodiode may be an area for checking process noise for noise removal by other components, not the photodiode.

Referring to FIG. 3B, each through-via structure 350B may include a via conductive layer 355b, a filling insulating film 356b, and a capping pattern 359b. A plurality of through-via structures 350B may be formed within via holes, respectively.

The via conductive layer 355b may be conformally formed on a sidewall and a bottom surface of the via hole within the pad region (PR). The via conductive layer 355b may electrically connect a first pad or a second pad of the first interconnection structure 150 and a first pad 255P1 of the second interconnection structure 250. The via conductive layer 355b may be disposed within the via hole to connect the first interconnection 155 and the second interconnection 255. The via conductive layer 355b may extend along a profile of the side and lower surfaces of the via hole.

In some embodiments, the via conductive layer 355b is formed together with the conductive layer 355L extending from the upper surface 110b of the first substrate 110, and may be a layer connected to the conductive layer 355L or separated from the conductive layer 355L and other via conductive layers. For example, the via conductive layer 355b may include, for example but not limited to, at least one of titanium (Ti), titanium nitride (TiN), tantalum (Ta), tantalum nitride (TaN), tungsten (W), aluminum (Al), copper (Cu), and any combination thereof.

In some embodiments, the filling insulating film 356b may be disposed on the via conductive layer 355b to fill at least a portion of the via hole. In some embodiments, an upper surface of the filling insulating film 356b may be concave. This may be due to, but is not limited to, a characteristic of a process of forming the filling insulating film 356b (for example, a deposition process and/or a planarization process). For example, the filling insulating film 356b may include a silicon-based insulating material (for example, silicon nitride, silicon oxide, and silicon oxynitride) and a high-k material (for example, hafnium oxide and aluminum oxide).

In some embodiments, the capping pattern 359b may be disposed on the via conductive layer 355b and the filling insulating film 356b. For example, a portion of the capping pattern 359b may protrude from an upper surface of the via conductive layer 355b. In some embodiments, the capping pattern 359b may be omitted.

The image sensor chip 10 according to the present embodiment may further include the first protective layer 280 that extends from the microlens layer 280L and is disposed on the peripheral area, for example, the light-shielding area (OB) and the pad region (PR). For example, the first protective layer 280 may be integrated with the microlens layer 280L.

The first protective layer 280 may extend on the light-shielding area (OB) and the pad region (PR) to provide a flat upper surface. In this case, the first protective layer 280 may also be referred to as a planarization layer. In some embodiments, the first protective layer 280 may extend to cover the light-shielding filter layer 165 and the plurality of through-via structures 350B in the chip-to-chip connection area (CR) in the light-shielding area (OB) to provide a flat upper surface, and may extend on the pad region (PR). The first protective layer 280 may be formed such that the bonding pad 390 is exposed in the pad region (PR).

In some embodiments, the first protective layer 280 may be a layer formed together on the light-shielding area (OB), the chip-to-chip connection area (CR), and the pad region (PR) in a deposition process for forming the micro-lens layer 280L of the pixel array region (PA). The first protective layer 280 may include the same material as the micro-lens layer 280L. For example, the first protective layer 280 may include a light-transmitting resin, such as a transparent photoresist material or a transparent thermosetting resin material.

The image sensor chip 10 according to the present embodiment may further include the second protective layer 290 formed on the microlens layer 280L and the first protective layer 280. The second protective layer 290 may extend along a surface of the microlens layer 280L and may be formed on an upper surface of the first protective layer 280. The second protective layer 290 may be formed relatively conformally. The second protective layer 290 may have a thickness smaller than that of the first protective layer 280. The second protective layer 290 may include a low temperature oxide (LTO). The second protective layer 290 may include an inorganic oxide such as, for example but not limited to, silicon oxide, titanium oxide, zirconium oxide, hafnium oxide, or any combination thereof. The second protective layer 290 may protect the microlens layer 280L from the outside. For example, the second protective layer 290 may protect the microlens layer 280L including an organic material by including an inorganic oxide film. In addition, the second protective layer 290 may improve the quality of the image sensor chip 10 by improving the light collection efficiency of the microlenses of the microlens layer 280L. For example, the second protective layer 290 may be formed in an area between the microlenses to reduce reflection, refraction, scattering, and the like of incident light reaching the space between the microlenses.

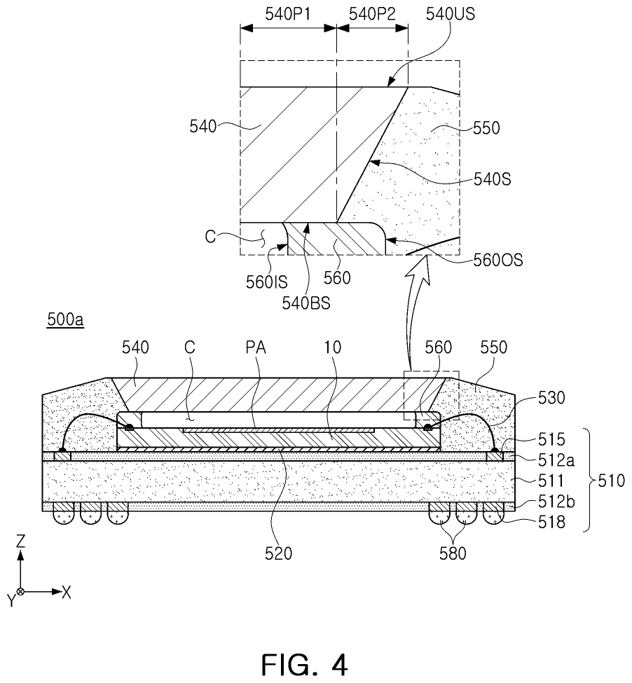

FIG. 4 is a cross-sectional view illustrating an image sensor package 500a according to one or more example embodiments.

Referring to FIG. 4, the image sensor package 500a of one or more example embodiments may have the same or similar features as those described with reference to FIGS. 1 to 3B, except that the transparent cover 540 has an inclined surface 540S extending directly from each of the uppermost surface 540US and the lowermost surface 540BS. The transparent cover 540 of the image sensor package 500a of the present embodiment may include a first portion 540P1 including a central region and a second portion 540P2 positioned outside the first portion 540P1. The second portion 540P2 may have the inclined surface 540S extending from the lowermost surface 540BS of the transparent cover 540 to the uppermost surface 540US. The inclined surface 540S may form an obtuse angle with the lowermost surface 540BS and an acute angle with the uppermost surface 540US, but is not limited thereto. In a planar view, the second portion 540P2 may have a shape of a right triangle. In a planar view, the transparent cover 540 may have a shape of an equilateral trapezoid. Based on this configuration, structural and morphological freedom of the transparent cover 540 may be sought.

FIG. 5 is a cross-sectional view illustrating an image sensor package 500b according to one or more example embodiments.

Referring to FIG. 5, the image sensor package 500b of one or more example embodiments may have the same or similar features as those described with reference to FIGS. 1 to 4, except that a second portion 540P2 of the transparent cover 540 has a step shape. The transparent cover 540 of the image sensor package 500b of the present embodiment may have a first portion 540P1 and the second portion 540P2 positioned outside the first portion 540P1. The first portion 540P1 may have a first side surface 540S1 extending from the lowermost surface of the transparent cover 540, and the second portion 540P2 may have a second side surface 540S2 extending from the uppermost surface 540US of the transparent cover 540. In addition, the second portion 540P2 may have an intermediate surface 540MS extending from one end of the first side surface 540S1 to one end of the second side surface 540S2, and the intermediate surface 540 MS may be parallel to each of the lowermost surface 540BS and the uppermost surface 540US. In a planar view, the transparent cover 540 may have a step shape corresponding to a step in the second portion 540P2. The step shape may be formed in the second portion 540P2. The first side surface 540S1 and the second side surface 540S2 may extend in a direction perpendicular to each of the lowermost surface 540BS and the uppermost surface 540US of the transparent cover 540. The first side surface 540S1 and the second side surface 540S2 may extend in parallel to each other. At least a portion of the dam 560 may be vertically spaced apart from the second portion 540P2 of the transparent cover 540.

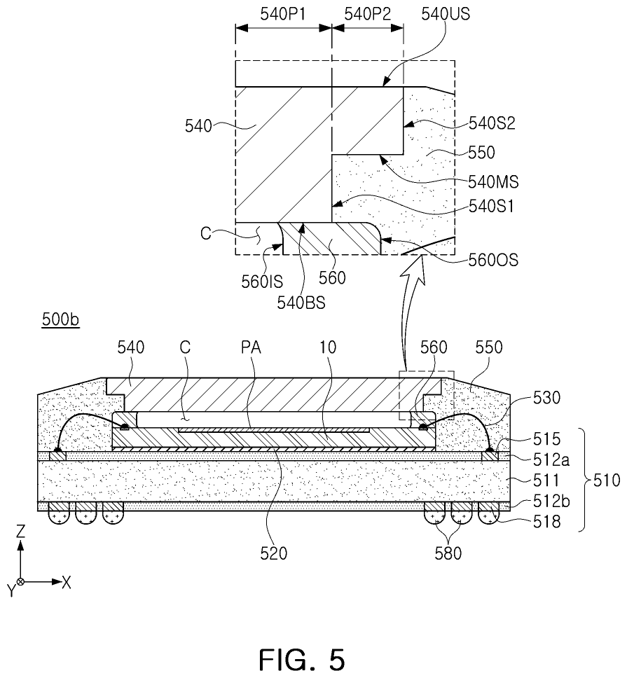

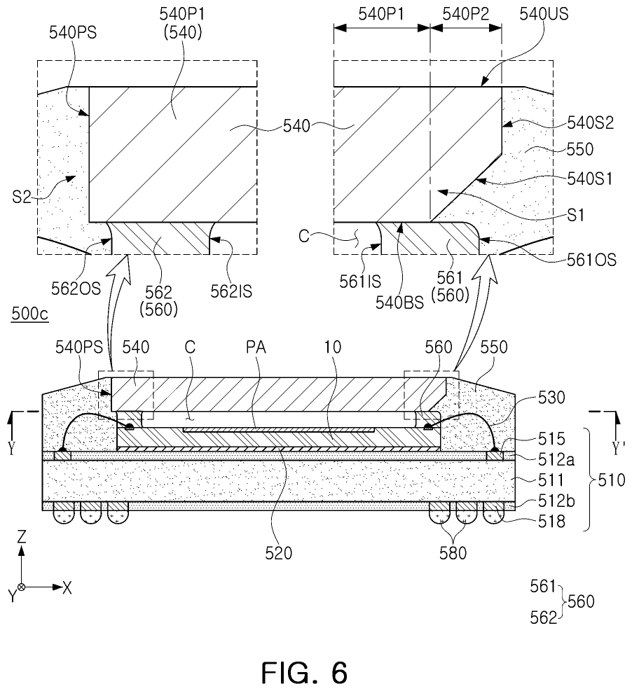

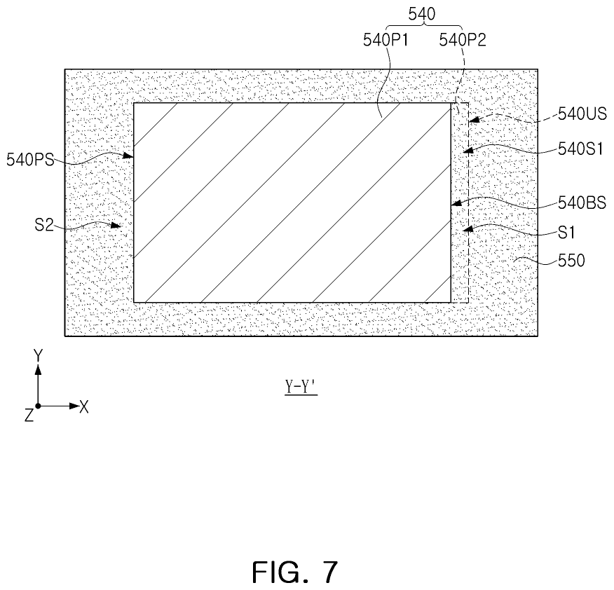

FIG. 6 is a cross-sectional view illustrating an image sensor package 500c according to one or more example embodiments, and FIG. 7 is a plan view illustrating a cross-section taken along a line Y-Y′ of FIG. 6.

Referring to FIGS. 6 and 7, the image sensor package 500c of one or more example embodiments may have features identical to or similar to those described with reference to FIGS. 1 to 5, except that an inclined surface 540S1 exists only on one side of the transparent cover 540. The dam 560 may have a first dam area 561, and a second dam area 562 other than the first dam area 561. The first portion 540P1 of the transparent cover 540 includes a first side portion S1 that contacts a portion of an upper surface of the first dam area 561 and a second side portion S2 that contacts the entire upper surface of the second dam area 562, and the second portion 540P2 of the transparent cover 540 may be located on the first side portion S1 of the first portion 540P1. A portion of the upper surface of the first dam area 561 contacts the lowermost surface 540BS of the first portion 540P1 of the transparent cover 540, and another portion of the upper surface of the first dam area 561 may be spaced apart from the inclined surface 540S1 of the second portion 540P2 of the transparent cover 540 in a vertical direction (for example, in the Z-axis direction). A vertical side surface 540PS may exist on the second side portion S2 adjacent to the second dam area 562 among the first portion 540P1 of the transparent cover 540, and the vertical side surface 540PS may not vertically overlap with the dam 560. An inner side surface 561IS of the first dam area 561 may have a concave curved shape toward the first dam area 561, but is not limited thereto. At least a portion of an upper end of an outer side surface 561OS of the first dam area 561 may have a rounded shape and may have a convex curved shape toward the encapsulant 550, but is not limited thereto. An inner side surface 562IS and an outer side surface 562OS of the second dam area 562 may have a concave curved shape toward the second dam area 562, but is not limited thereto. Respective upper ends of the inner side surface 562IS and the outer side surface 562OS of the second dam area 562 may be in contact with the lowermost surface 540BS of the transparent cover 540. The image sensor package 500c of the present embodiment may improve a degree of structural freedom of the transparent cover 540 by freely adjusting an area of the transparent cover 540 where the inclined surface 540S1 spaced apart from the upper surface of the dam 560 is located.

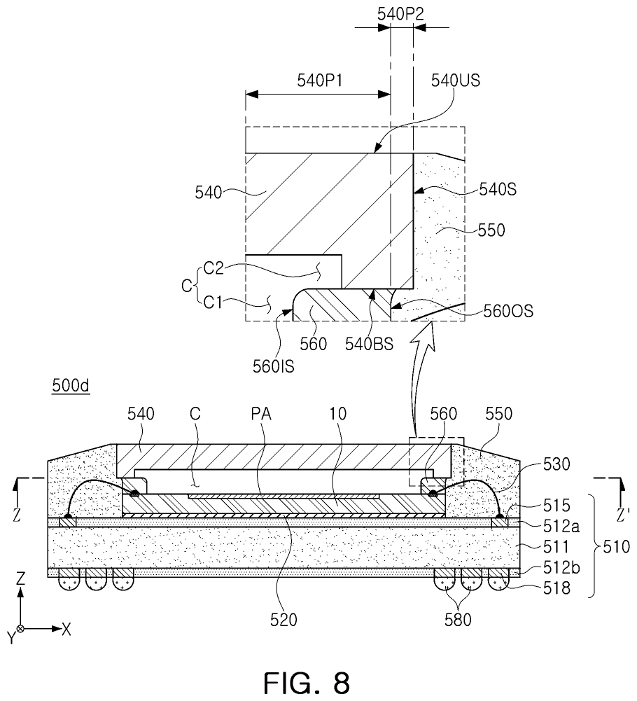

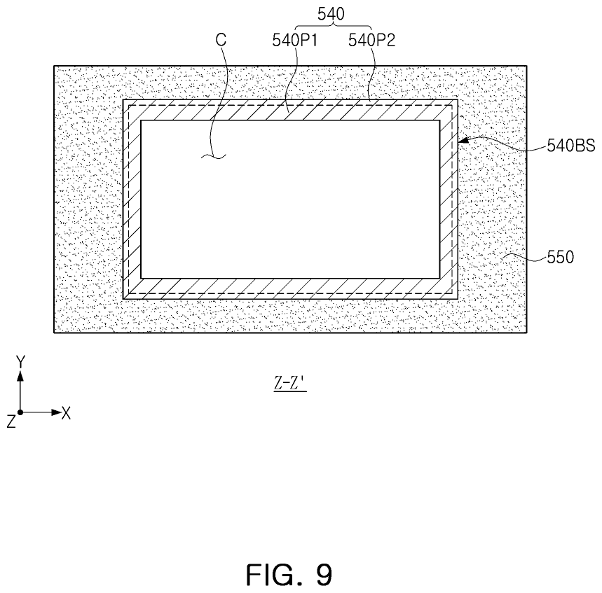

FIG. 8 is a cross-sectional view illustrating an image sensor package 500d according to one or more example embodiments, and FIG. 9 is a plan view illustrating a cross-section along a line Z-Z′ of FIG. 8.

Referring to FIGS. 8 and 9, the image sensor package 500d of one or more example embodiments may have the same or similar features as those described with reference to FIGS. 1 to 7, except that an area in which the dam 560 and the transparent cover 540 are separated from each other is located inwardly of the transparent cover 540. The transparent cover 540 of the image sensor package 500d of the present embodiment may have a first portion 540P1 and a second portion 540P2 located on the outside of the first portion 540P1. The first portion 540P1 may have an inner-side region that is spaced apart in the vertical direction from the dam 560, and an outer-side region that is in contact with a portion of the upper surface of the dam 560. The first portion 540P1 may have an intermediate surface that is spaced apart in the vertical direction from the upper surface of the dam 560 and an inner side surface that extends from the lower surface 540BS of the transparent cover 540 to the intermediate surface. The inner side surface may extend in a direction perpendicular to the lower surface 540BS of the transparent cover 540, but is not limited thereto, and may have an inclined inner side surface such as the inclined surface (e.g., 540S1, see FIG. 1 in the above-described embodiment of the image sensor package 500). The second portion 540P2 does not overlap with the dam 560 in the vertical direction, and may correspond to a portion that protrudes outwardly from the side surface of the dam 560, but is not limited thereto. A separation space (C) may include a first separation space C1 between the transparent cover 540 and the image sensor chip 10, and a second separation space C2 between the transparent cover 540 and the dam 560. The first separation space C1 and the second separation space C2 may be connected to each other. The dam 560 may surround at least a portion of the first separation space C1, and the transparent cover 540 may surround the second separation space C2. The dam 560 may have an inner side surface 560IS and an outer side surface 560OS positioned opposite to the inner side surface 560IS. The outer side surface 560OS of the dam 560 may have a concave curved shape toward the dam 560, but is not limited thereto. The lower end of the outer side surface 560OS of the dam 560 may be in contact with the upper surface of the second protective layer 290 of the image sensor chip 10, and the upper end of the outer side surface 560OS of the dam 560 may be in contact with the lower surface 540BS of the transparent cover 540. The lower end of the inner side surface 560IS of the dam 560 may be in contact with the upper surface of the second protective layer 290 of the image sensor chip 10, and the upper end of the inner side surface 560IS of the dam 560 may be vertically spaced apart from the first portion 540P1 of the transparent cover 540 and may be in contact with the separation space (C). At least a portion of the upper end of the inner side surface 560IS of the dam 560 may have a rounded shape and may have a convex curved shape toward the separation space (C), but is not limited thereto.

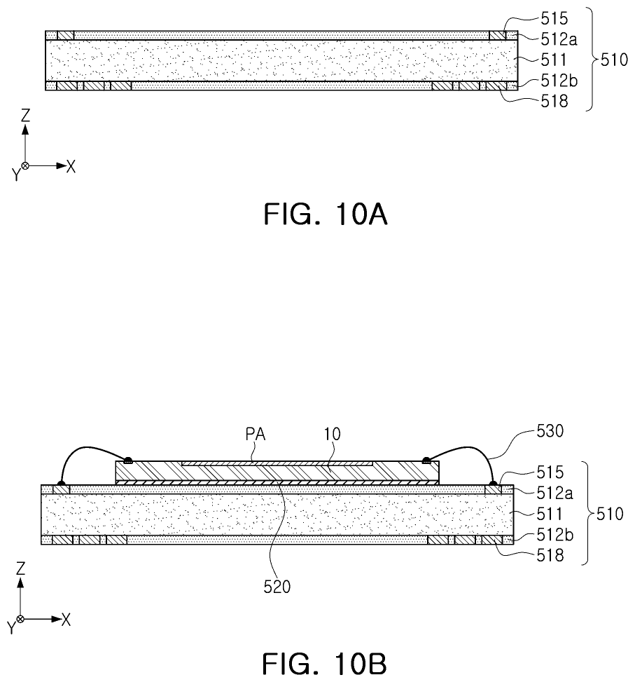

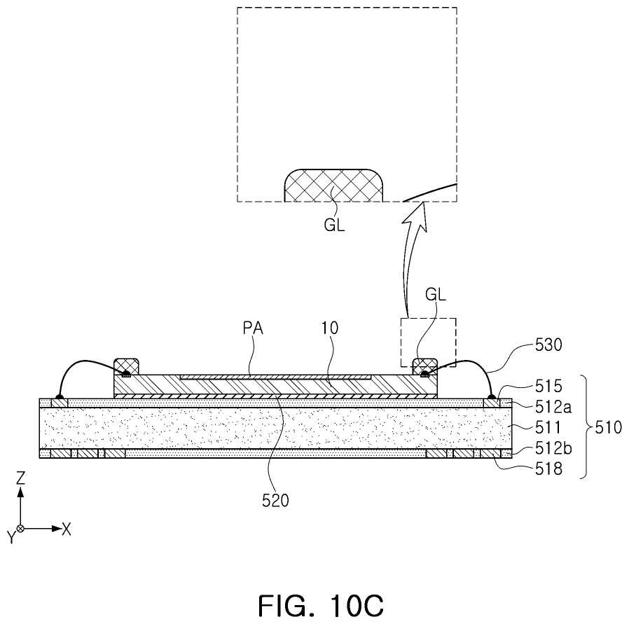

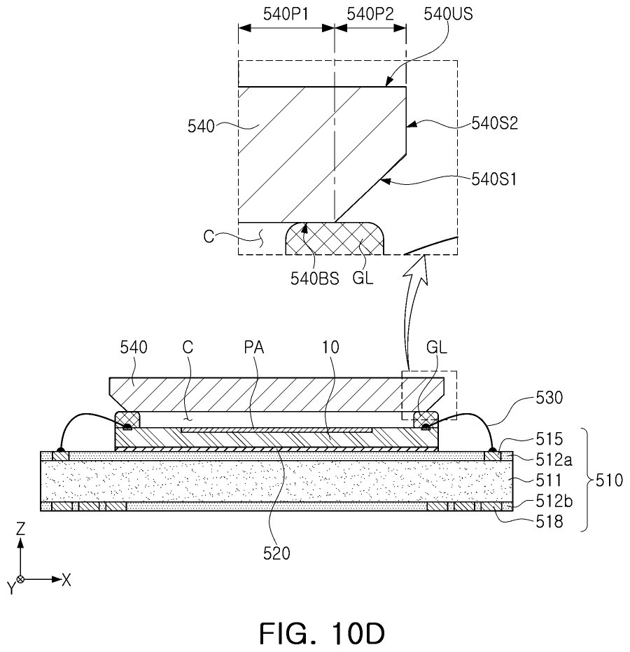

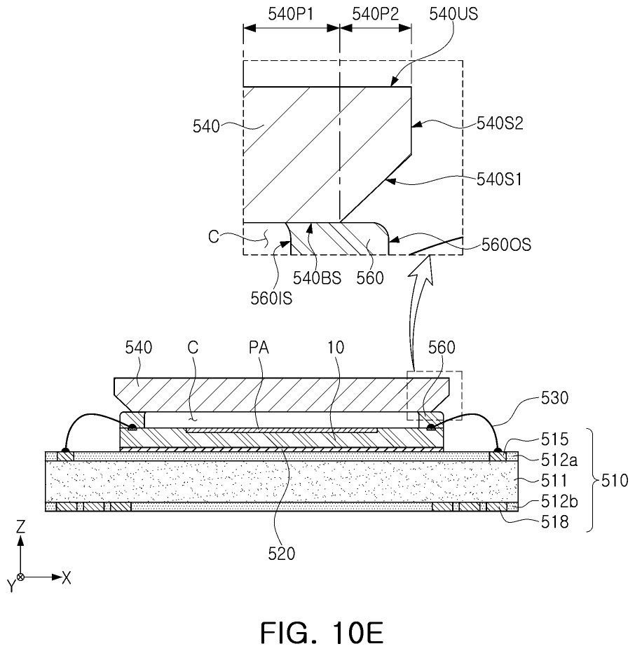

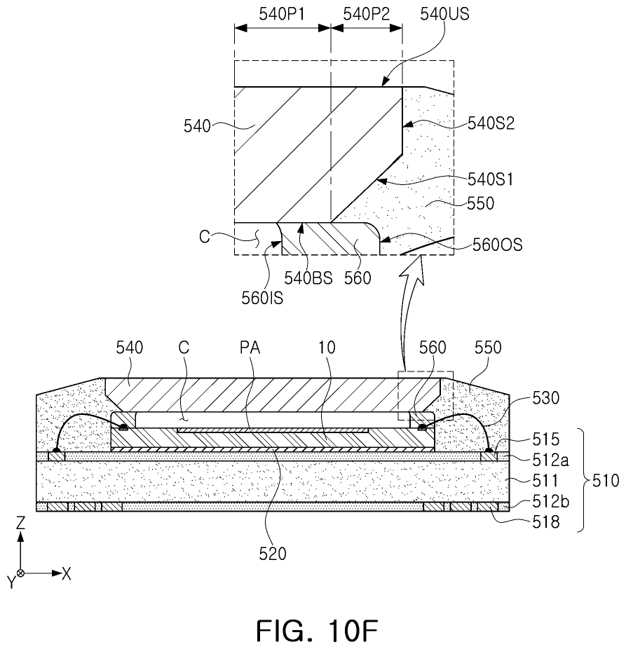

FIGS. 10A to 10F are cross-sectional views schematically illustrating a manufacturing process of an image sensor package according to one or more example embodiments.

Referring to FIG. 10A, a package substrate 510 may be prepared. The package substrate 510 may include a substrate body 511, an upper pad 515, a lower pad 518, and upper and lower passivation layers 512a and 512b. The upper pad 515 and the lower pad 518 may be electrically connected to each other by an interconnection structure (not illustrated) inside the substrate body 511. An upper surface of the upper pad 515 may be exposed from the upper passivation layer 512a, and a lower surface of the lower pad 518 may be exposed from the lower passivation layer 512b.

Referring to FIG. 10B, an image sensor chip 10 may be disposed on a package substrate 510, and the image sensor chip 10 may be electrically connected to the package substrate 510 through a conductive wire 530. The image sensor chip 10 may be attached to the package substrate 510 through an adhesive film 520 disposed on a bottom of the image sensor chip 10. The conductive wire 530 may be electrically connected to a plurality of chip pads (not illustrated) on the image sensor chip 10 and corresponding upper pads 515 on the package substrate 510.

Referring to FIG. 10C, an adhesive material (GL) may be disposed along an outer region of an image sensor chip 10. A pixel array region (PA) in which active pixels are arranged may be located at the central portion of the image sensor chip 10, and an adhesive material (GL) may be disposed on an upper surface of the image sensor chip 10 to surround the pixel array region (PA). The adhesive material (GL) may be disposed along a perimeter of the outer area of the image sensor chip 10 through dispensing. The image sensor chip 10 may be disposed such that the pixel array region (PA) faces upwardly.

Referring to FIG. 10D, a transparent cover 540 may be disposed on the adhesive material (GL). The transparent cover 540 may correspond to a shape in which at least a portion of an area corresponding to four edges located on a lower surface of a rectangular parallelepiped preliminary transparent cover (not illustrated) is removed, but is not limited thereto. The transparent cover 540 may correspond to one of transparent covers disposed on the various image sensor packages 500, 500a, 500b, 500c, and 500d corresponding to the above-described embodiments. The transparent cover 540 may be spaced apart from the upper surface of the image sensor chip 10 by a height of the adhesive material (GL) in the vertical direction. A space (C) may be positioned between the transparent cover 540 and the image sensor chip 10, and the space (C) may be defined by the adhesive material (GL). The lower surface 540BS of the transparent cover 540 may be in contact with the adhesive material (GL), and the inclined surface 540S1 of the transparent cover 540 may be spaced apart from the adhesive material (GL) in the vertical direction. The adhesive material (GL) may be disposed to overlap with the transparent cover 540 in the vertical direction.

Referring to FIG. 10E, a dam 560 disposed between the image sensor chip 10 and the transparent cover 540 may be formed. The dam 560 may be formed by curing the adhesive material (GL, see FIG. 10D) that was disposed between the image sensor chip 10 and the transparent cover 540 in the previous process (see FIG. 10D). At least a portion of the upper surface of the dam 560 may be in contact with the lower surface of the transparent cover 540. According to one or more example embodiments, an upper end of one side surface of the dam 560, contacting the lower surface 540BS of the transparent cover 540, may have a concave curved shape toward the dam 560, and an upper end of one side surface the dam 560, not contacting the lower surface 540BS of the transparent cover 540, may have a convex curved shape toward the outside of the dam 560, but the disclosure is not limited thereto. Another portion of the upper surface of the dam that does not contact the lower surface 540BS of the transparent cover 540 may be spaced apart in a vertical direction from the inclined surface 540S1 of the transparent cover 540, and may have a shape of an inclined surface located between the upper surface of the dam 560 and the lower surface of the dam 560, but is not limited thereto.

Referring to FIG. 10F, an encapsulant 550 may be formed. The encapsulant 550 may cover at least respective portions of the image sensor chip 10, the dam 560, the conductive wire 530, and the transparent cover 540, on the package substrate 510. The encapsulant 550 may cover at least a portion of the upper surface of the dam 560. The encapsulant 550 may cover the inclined surface 540S1 and the side surface 540S2 of the transparent cover 540.

Referring to FIGS. 1 and 2, external connection conductors 580 may be disposed under the package substrate 510 to form the image sensor package 500 of the present embodiment. The external connection conductors 580 may be attached to a lower surface of the lower pads 518.

As set forth above, according to example embodiments, by introducing a transparent cover with at least a portion of a lower surface removed so as to be exposed from an upper surface of a dam structure, damage such as cracks may be effectively prevented by significantly reducing an influence of thermal stress.

While example embodiments have been illustrated and described above, it will be apparent to those skilled in the art that modifications and variations could be made without departing from the scope of the disclosure as defined by the appended claims and their equivalents.

What is claimed is:

1. An image sensor package comprising:
a package substrate;
an image sensor chip disposed on the package substrate and including a pixel array region, in which active pixels are arranged, and a pad region located outside the pixel array region, a plurality of chip pads being disposed in the pad region;
a dam disposed in the pad region of the image sensor chip, the dam being provided on at least a portion of the plurality of chip pads;
a transparent cover disposed on the dam, the transparent cover having a first portion, and a second portion located outside of the first portion; and
an encapsulant provided on at least a portion of a side surface of the image sensor chip, and at least a portion of a side surface of the dam,
wherein the dam has a lower surface contacting the pad region and an upper surface facing opposite the lower surface,
wherein the first portion contacts a portion of the upper surface of the dam, and
wherein a width of a contact surface between the first portion and the portion of the upper surface of the dam in a first direction is smaller than a width of the upper surface of the dam in the first direction.

2. The image sensor package of claim 1, wherein a lowermost surface of the transparent cover has a first width in the first direction, and
wherein an uppermost surface of the transparent cover has a second width larger than the first width in the first direction.

3. The image sensor package of claim 1, further comprising:
a microlens layer disposed on the active pixels, in the pixel array region;
a first protective layer extending from the microlens layer and extending over at least a portion of the pad region; and
a second protective layer disposed on the microlens layer and the first protective layer.

4. The image sensor package of claim 3, wherein the lower surface of the dam is in contact with at least a portion of an upper surface of the second protective layer.

5. The image sensor package of claim 1, wherein the second portion has an inclined surface extending from a lowermost surface of the transparent cover, and
wherein a first dihedral angle between the lowermost surface of the transparent cover and the inclined surface is an obtuse angle.

6. The image sensor package of claim 5, wherein the second portion has a side surface extending from one end of an uppermost surface of the transparent cover to one end of the inclined surface, and
wherein a second dihedral angle between the uppermost surface of the transparent cover and the side surface of the second portion is smaller than the first dihedral angle.

7. The image sensor package of claim 5, wherein the inclined surface extends from the lowermost surface of the transparent cover to an uppermost surface of the transparent cover.

8. The image sensor package of claim 5, wherein the inclined surface of the second portion contacts the encapsulant.

9. The image sensor package of claim 1, wherein the first portion has a first side surface extending in a second direction intersecting with a lowermost surface of the transparent cover, and
wherein the second portion has a second side surface extending in a third direction intersecting with an uppermost surface of the transparent cover, and an intermediate surface extending from one end of the first side surface to one end of the second side surface in a fourth direction intersecting the second direction and the third direction.

10. The image sensor package of claim 1, wherein the dam has a first dam area, and a second dam area other than the first dam area,
wherein the first portion of the transparent cover includes a first side portion contacting a portion of an upper surface of the first dam area, and a second side portion contacting an entirety of an upper surface of the second dam area, and
wherein the second portion of the transparent cover is located on the first side portion of the first portion.

11. The image sensor package of claim 1, wherein the first portion includes an inner-side region vertically spaced apart from the dam, and an outer-side region contacting the portion of the upper surface of the dam.

12. The image sensor package of claim 1, wherein at least a portion of the second portion does not vertically overlap with the dam.

13. The image sensor package of claim 1, wherein the dam is spaced apart from the pixel array region and surrounds the pixel array region.

14. The image sensor package of claim 13, wherein the image sensor chip further includes a light-shielding area disposed along a periphery of the pixel array region, and
wherein the dam is spaced apart from the light-shielding area and surrounds the light-shielding area.

15. The image sensor package of claim 1, further comprising external connection conductors disposed on or below the package substrate and electrically connected to the image sensor chip.

16. An image sensor package comprising:
a package substrate;
an image sensor chip disposed on the package substrate and including active pixels arranged in a central portion of the image sensor chip;
a dam surrounding the active pixels and disposed along an outer region of the image sensor chip;
a transparent cover provided on the dam; and
an encapsulant provided on at least a portion of a side surface of the image sensor chip, and at least a portion of a side surface of the dam,
wherein the dam overlaps the transparent cover in a vertical direction, and
wherein at least a portion of the transparent cover is spaced apart from an upper surface of the dam in the vertical direction.

17. The image sensor package of claim 16, further comprising a separation space defined between the transparent cover and the image sensor chip,
wherein the separation space extends between the transparent cover and the dam.

18. The image sensor package of claim 16, wherein the transparent cover has an intermediate surface spaced apart from the upper surface of the dam in the vertical direction, and an inner side surface extending from a lower surface of the transparent cover to the intermediate surface,
wherein the inner side surface is vertical or inclined with respect to the lower surface of the transparent cover.

19. An image sensor package comprising:
a package substrate including a plurality of upper pads;
an image sensor chip disposed on the package substrate, the image sensor chip including a pixel array region, in which active pixels are arranged, and a pad region located outside of the pixel array region, a plurality of chip pads being disposed in the pad region;
a conductive wire electrically connecting the plurality of upper pads of the package substrate and the plurality of chip pads of the image sensor chip;
a dam disposed on the pad region of the image sensor chip, the dam being provided on at least respective portions of the plurality of chip pads and the conductive wire;
a transparent cover provided on the dam; and
an encapsulant provided on at least a portion of a side surface of the image sensor chip, and at least a portion of a side surface of the dam,
wherein a portion of an upper surface of the dam is in contact with a lower surface of the transparent cover, and
wherein another portion of the upper surface of the dam is in contact with the encapsulant.

20. The image sensor package of claim 19, wherein the transparent cover has an inclined surface extending from one end of the lower surface, and
wherein the inclined surface extends along a perimeter of the transparent cover.
